(19) United States
(12) Patent Application Publication
(10) Pub. No.: US 2025/0285827 A1
(43) Pub. Date: Sep. 11, 2025

(54) CHARGED PARTICLE BEAM DEVICE

(71) Applicant: HITACHI HIGH-TECH SCIENCE CORPORATION, Tokyo (JP)

(72) Inventors: Hiroshi OBA, Tokyo (JP); Koji NAGAHARA, Tokyo (JP); Yasuhiko SUGIYAMA, Tokyo (JP)

(21) Appl. No.: 18/687,696

(22) PCT Filed: Sep. 1, 2021
(86) PCT No.: PCT/JP2021/032121

§ 371 Date: May 22, 2025

(51) Int. Cl. H01J 37/09; H01J 37/10

(52) U.S. Cl. CPC H01J 37/09; H01J 37/10; H01J 2237/0455; H01J 2237/31749

(57) ABSTRACT

A focused ion beam lens column (17) of this charged particle beam device includes an ion source (41) and an ion optics (42). The ion optics (42) includes a diaphragm member (54b) provided with a plurality of through-holes that are switched in order to cause a portion of a beam of the ions (an ion beam) generated by the ion source (41) to pass therethrough. Switching is performed to select any of the plurality of through-holes while the optical conditions of the ion optics (42) are maintained in a predetermined projection mode (second projection mode). The plurality of through-holes includes fine round holes for observation that are positioned in the center of the ion beam, first rectangular holes for processing that are positioned off the center of the ion beam, and second rectangular holes for observation and processing that are positioned off the center of the ion beam.

### CROSS REFERENCE

The present Application for Patent is a 371 national phase filing of International Patent Application No. PCT/JP2021/032121, by OBA et al., entitled “CHARGED PARTICLE BEAM DEVICE,” filed Sep. 1, 2021, assigned to the assignee hereof, and expressly incorporated by reference herein.

### TECHNICAL FIELD

The present t invention relates to a charged particle beam device.

### BACKGROUND ART

Conventionally, there is known a beam device that repeatedly performs a process of observing and processing a sample to form a cross section by ion beam irradiation and a process of acquiring a cross section image by electron beam irradiation (see, for example, Patent Document 1).

Conventionally, there is known a beam device that is equipped with an optics provided with a mask with an aperture of a desired shape and which irradiates a sample with a beam in projection mode in which a shaped beam cut through the mask matches a processed shape (see Patent Document 2).

For example, a charged particle beam device equipped with a plasma ion source can obtain a probe current of 100 nA or more and can reduce a processing time during large-area processing. On the other hand, the probe diameter increases as the probe current increases. In addition, the area of thin current density outside the main beam becomes larger, and the edges of the cross section obtained by machining are shaved off to become a large rounded chamfered shape. When a sample is processed with a sharp-edged beam by reducing a probe current at the time of creating a large-area cross-section, the processing time increases. Therefore, Patent Document 2 discloses a method of forming a sharp-edged beam by increasing a probe current.

In the conventional method, the probe current is changed from two levels to three level during in cross-sectional processing, and the processing starts with the highest prove current while changing the prove current from the highest level to the lowest level, thereby achieving processing with sharp edges. In this case, processing with a large probe current requires leaving a finishing allowance, but since the area is large as described above, it is necessary to perform processing on an area as close as possible to the desired processing position to reduce the processing time.

In the conventional method in which a mask is not used for projection, a beam is collimated by a condenser lens (CL), and a sample is processed by a beam focused by an objective lens, since the beam has a small spot-like shape, the beam is made to scan over the sample to accurately determine the processing position through observation of the sample.

### DOCUMENT OF RELATED ART

### Patent Document

Patent Document 1: Japanese Patent Application Publication No. 2013-197044

Patent Document 2: Japanese Patent Application Publication No. 2013-214521

### DISCLOSURE

### Technical Field

Since the beam shape in projection mode is large to be used for the processing, it is difficult to accurately determine the processing position by observing a sample as in the past. Therefore, a possible method can be considered to use focusing mode during positioning for processing and to use projection mode during processing.

When observing and processing a sample with an ion beam of the beam device described above, switching between the optical conditions for observation and the optical condition for processing deteriorates positional reproducibility, which may result that the processing position does not coincide with the desired position. For example, when the focusing mode in which an ion beam is substantially collimated by a condenser lens and the collimated beam is focused onto a sample by an objective lens is set as the optical condition for observation, and the projection mode is set as the optical condition for processing, there may be a problem in that the processing position can easily deviate from the desired position depending on lens voltage, aperture positioning accuracy, etc.

The purpose of the present invention is to provide a charged particle beam device that can improve the accuracy of the processing position at which positional processing with a charged particle beam is performed.

### Technical Field

In order to solve the problems described above, a charged particle beam device according to the present invention includes: a charged particle source generating charged particles; and an optics including a diaphragm member where a plurality of through-holes is formed that are switched to pass a portion of a beam of the charged particles generated from the charged particle source, the optics irradiating a sample with the beam of charged particles passing through each of the plurality of through-holes, in which the plurality of through-holes is switched to any one in a state in which the optics maintains a predetermined optical condition, and the plurality of through-holes comprises at least a first through-hole positioned at a center of the beam of the charged particles and a second through-hole placed off-center of the beam of the charged particles.

In the configuration, In the above configuration, the plurality of through-holes includes at least the first through-hole, the second through-hole, and a third through-hole that is placed off-center of the beam of charged particles, a size of the third through-hole in a direction of displacement from the center of the beam of the charged particles being substantially equal a size of the first through-hole and a size of the third through-hole in a direction orthogonal to the direction of displacement from the center of the beam of charged particles being substantially equal to a size of the second through-hole.

In order to solve the problems described above, a charged particle beam device according to the present invention includes: a charged particle source generating charged particles; and an optics comprising a plurality of diaphragm members where at least one through-hole is formed that passes a portion of a beam of the charged particles generated from the charged particle source, the optics irradiating a sample with the beam of charged particles passing through the through-holes of each of the plurality of diaphragm members, in which the plurality of diaphragm members does not interfere with one another with respect to passage of the beam of charged particles and comprises, in a state in which the optics maintains a predetermined optical condition, at least a first diaphragm member having a first through-hole placed at a center of the beam of charged particles and a second diaphragm member having a second through-hole placed off-center of the beam of charged particles.

In the configuration, the at least one through-hole formed on the second diaphragm member may include: the second through-hole; and a third-through-hole that is placed off-center of the beam of charged particles, in a state in which the optics maintains a predetermined optical condition, a size of the third through-hole in a direction of displacement from the center of the beam of charged particles being equal to a size of the first through-hole and a size of the third through-hole in a direction orthogonal to the direction of displacement from the center of the beam of charged particles being equal to a size of the second through-hole.

In the configuration, an edge of each of the second and third through-holes closest to the center of the beam of charged particles may be of a linear shape in parallel to the direction orthogonal to the direction of displacement from the center of the beam of charged particles.

In the configuration, the optics includes: a condenser lens placed between the charged particle source and the diaphragm member to focus the beam of charged particles; and an objective lens placed between the diaphragm member and the sample to focus the beam of charged particles on the sample, wherein the predetermined optical condition, with lens power in case of focusing the beam of charged particles on the sample in a beam shape cut by the diaphragm member with the diaphragm member as a light source by the objective lens, based on the Koehler illumination method, and focusing the beam of charged particles on a predetermined location of the objective lens by the condenser lens as standard lens power, is that lens power of the condenser lens is greater than or equal to 0.8 times and less than 1.0 times the standard lens power.

### Advantageous Effects

According to the present invention, due to the inclusion of diaphragm member comprising the first through-hole and the second through-hole that can be witched while maintaining the optical conditions, observation and can be switched, for example, by switching between the first through-hole for observation and the second through-hole for processing, and the positional accuracy of the position processed by a charged particle beam can be improved.

### DESCRIPTION OF RELATED ART

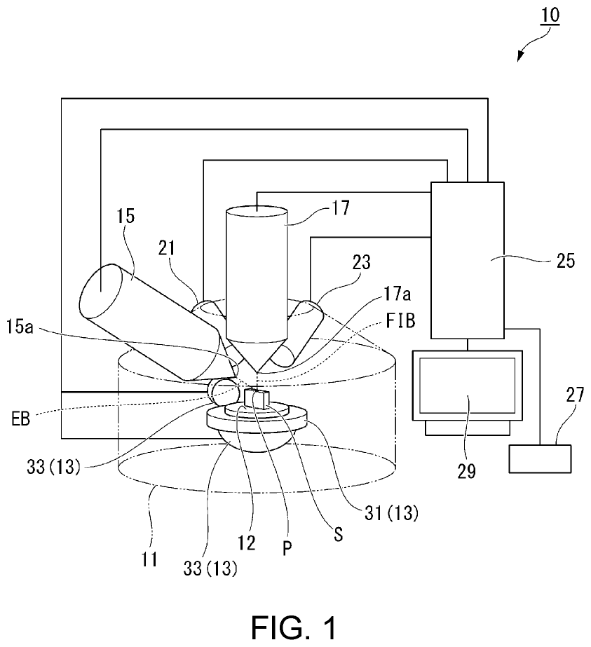

FIG. 1 is a view illustrating the construction of a charged particle beam device in one embodiment of the present invention.

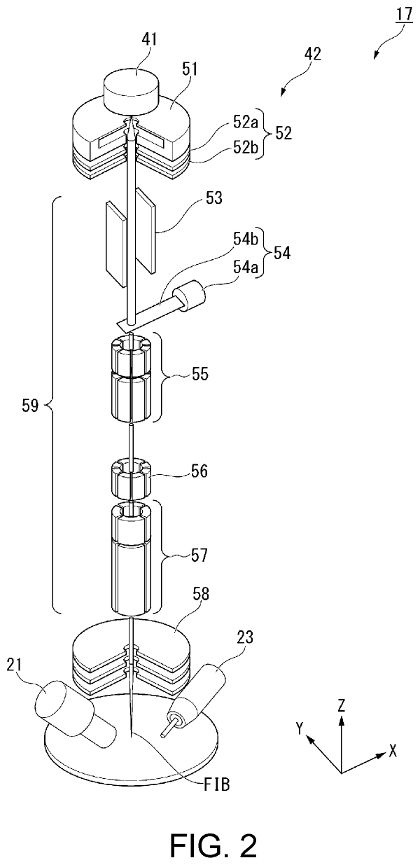

FIG. 2 is a view illustrating the construction of a focused ion beam column in one embodiment of the present invention.

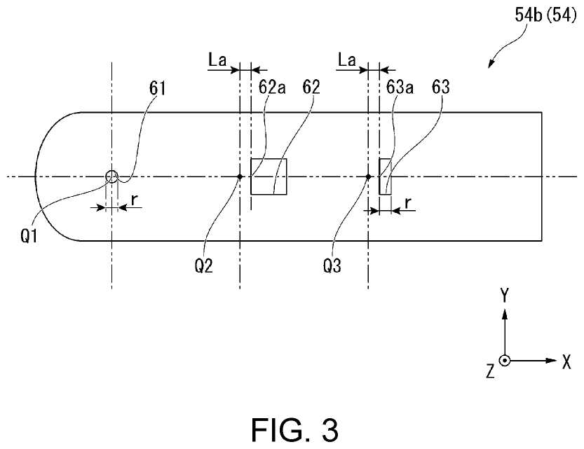

FIG. 3 is a view illustrating the construction of a movable diaphragm of a focused ion beam column in one embodiment of the present invention.

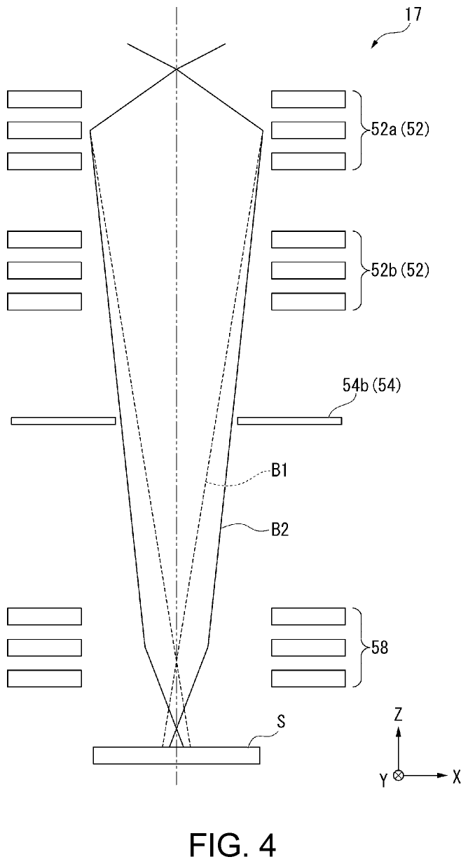

FIG. 4 is a view illustrating an example of an ion beam trajectory according to an application voltage for a condenser lens in projection mode of a focused ion beam column in one embodiment of the present invention.

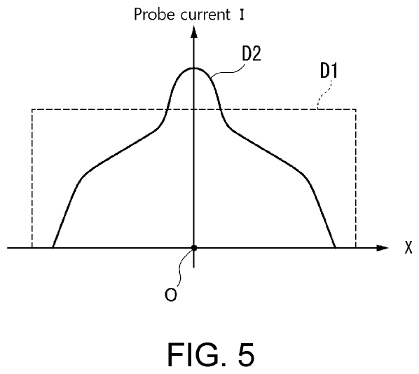

FIG. 5 is a view illustrating an example of a prove current intensity distribution on a sample surface, corresponding to the beam trajectory shown in FIG. 4.

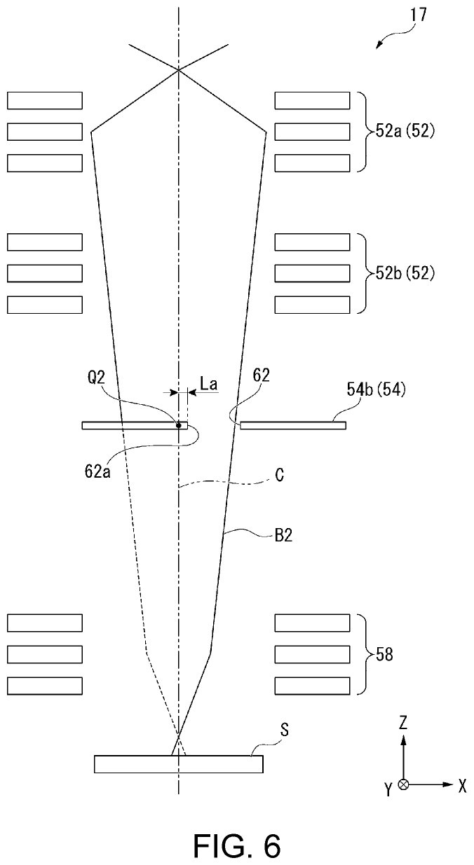

FIG. 6 is a view illustrating an example of a position corresponding to a beam center, in a diaphragm member of a movable diaphragm of a focused ion beam column in one embodiment of the present invention.

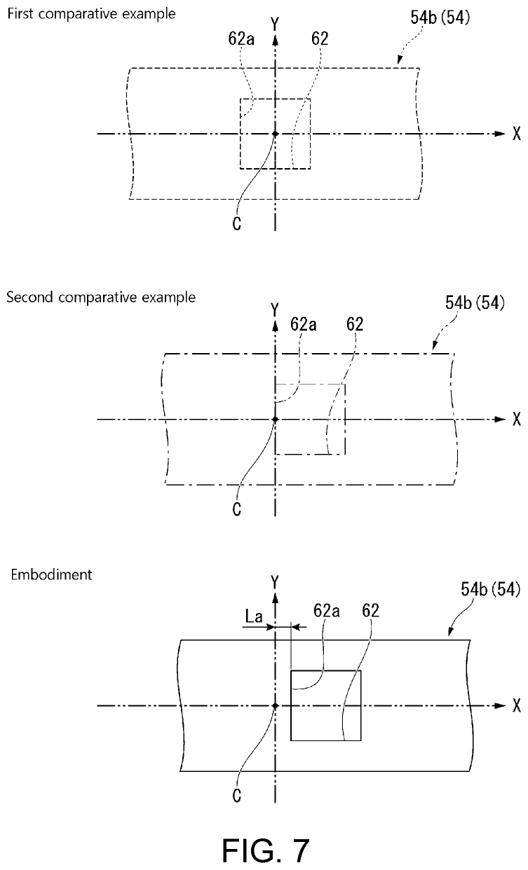

FIG. 7 is a view illustrating an example of a position corresponding to a beam center in a first rectangular hole for processing, in a movable diaphragm of a focused ion beam column in one embodiment of the present invention.

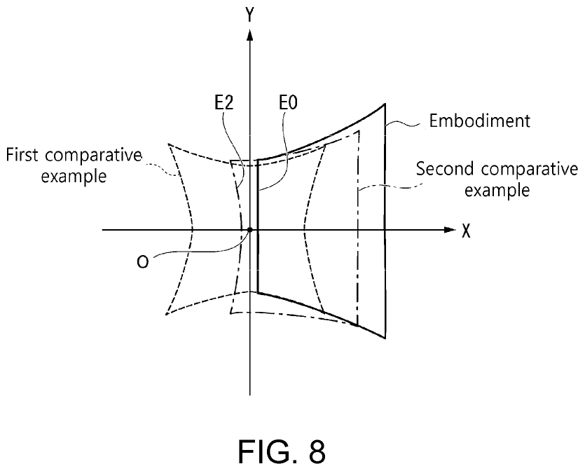

FIG. 8 is a view illustrating an example of the contour of a processing range on the sample surface according to the position of the first rectangular hole for processing shown in FIG. 7.

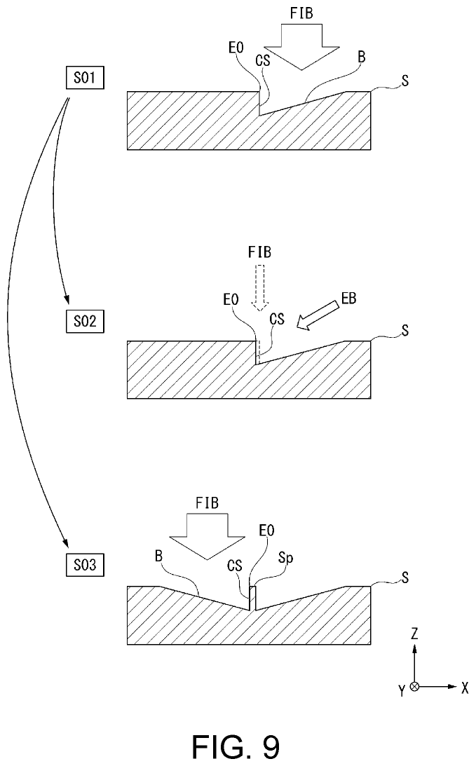

FIG. 9 is a view illustrating an example of observation and processing of a sample by a charged particle beam device in one embodiment of the present invention.

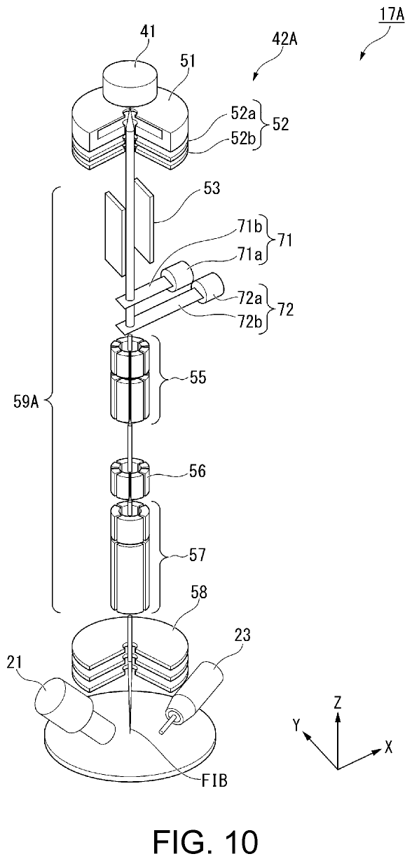

FIG. 10 is a view illustrating the construction of a focused ion beam column in a modification to one embodiment of the present invention.

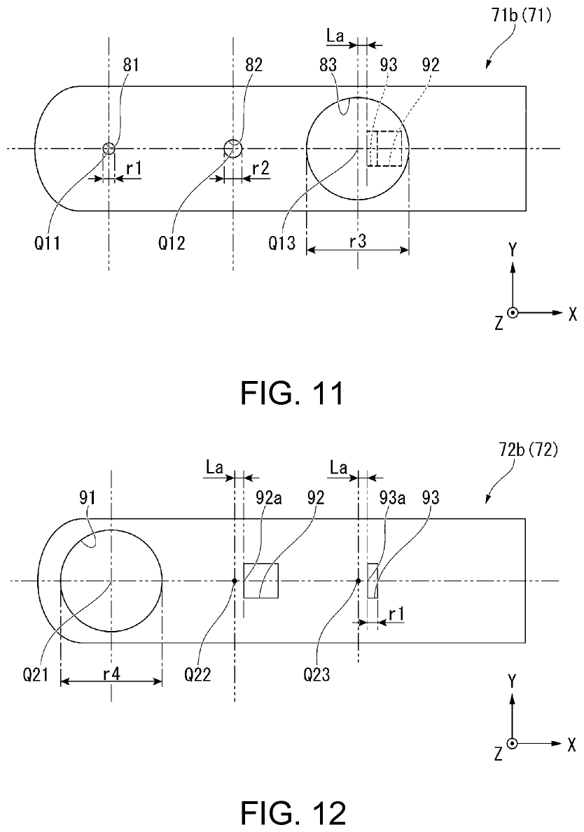

FIG. 11 is a view illustrating the construction of a first movable diaphragm of a focused ion beam column in a modification to one embodiment of the present invention.

FIG. 12 is a view illustrating the construction of a second movable diaphragm of a focused ion beam column in a modification to one embodiment of the present invention.

### BEST MODE

Hereinafter, a charged particle beam device 10 according to one embodiment of the present invention will be described with reference to the accompanying drawings.

### Charged Particle Beam Device

FIG. 1 is a view illustrating the construction of a charged particle beam device in one embodiment.

The charged particle beam device 10 includes a sample chamber 11, a sample holder 12, a sample stand 13, an electron beam column 15 fixed to the sample chamber 11, and a focused ion beam column 17 fixed to the sample chamber 11.

The charged particle beam device 10 includes, for example, a secondary charged particle detector 21 as a detector fixed to the sample chamber 11. The charged particle beam device 10 includes a gas supply unit 23 that supplies gas to the surface of a sample S. The charged particle beam device 10 includes a control device 25 that collectively controls the operation of the charged particle beam device 10 while being disposed outside the sample chamber 11, an input device 27 connected to the control device 25, and a display device 29 connected to the control device 25.

Herein, X-axis, Y-axis, and Z-axis directions, which are orthogonal to each other in 3D space, are parallel to the respective axes. For example, the Z-axis direction is parallel to the top-to-bottom direction (for example, vertical direction) of the charged particle device 10. The X-axis and Y-axis directions are parallel to a reference plane (for example, horizontal plane) that is orthogonal to the top-to-bottom direction of the charged particle beam device 10.

The sample chamber 11 is defined by an airtight, pressure-tight case capable of maintaining the desired reduced pressure. The sample chamber 11 can be evacuated by an air exhauster (not shown) until the interior of the sample chamber 11 has the desired reduced pressure.

The sample holder 12 fixes the sample S.

The sample stand 13 is disposed inside the sample chamber 11. The sample stand 13 includes a stage 31 that supports the sample holder 12 and a stage drive mechanism 33 that collectively three-dimensionally moves and rotates the stage 31 and the sample holder 12.

The stage drive mechanism 33 moves the stage 31 backwards and forwards along each of the X-axis, Y-axis, and Z-axis directions, for example. The stage drive mechanism 33, for example, rotates the stage 31 by an appropriate angle around each of the predetermined rotation and tilt axes. For example, the rotation axis is set relative to the stage 31. The stage 31 is parallel to the vertical direction of the charged particle beam device 10 when the stage 31 is in a predetermined reference position around the tilt axis. For example, the tilt axis is parallel to a direction perpendicular to the top-to-bottom direction of the charged particle beam device 10. The stage drive mechanism 33, for example, rotates the stage 31 eccentrically around the rotation axis and the tilt axis. The stage drive mechanism 33 is controlled by control signals that are output from the control device 25 according to on the operation modes of the charged particle beam device 10.

The electron beam column 15 directs an electron beam (EB) at an irradiation target object within a predetermined irradiation region inside the sample chamber 11. The electron beam column 15 is positioned, for example, such that the electron beam emission end 15a thereof obliquely faces the stage 31 in a tilt direction inclined by a predetermined angle with respect to the top-to-bottom direction of the charged particle beam device 10. The electron beam column 15 is fixed to the sample chamber 11 such that the optical axis of the electron beam is parallel to the tilt direction.

The electron beam column 15 is equipped with an electron source that generates electrons and with an electron optics that focuses and deflects the electrons emitted from the electron source. The electron optics is equipped with, for example, an electromagnetic lens and a deflector. The electron source and electron optics are controlled by control signals output from the control device 25 according to the electron beam irradiation position and irradiation conditions.

The focused ion beam column 17 directs a focused ion beam at an irradiation target object disposed within a predetermined irradiation region inside the sample chamber 11. The focused ion beam column 17, for example, is positioned such that the focused ion beam emission end 17a thereof faces the stage 31 in the top-to-bottom direction of the charged particle beam device 10. The focused ion beam column 17 is fixed to the sample chamber 11 such that the optical axis of the focused ion beam is parallel to the top-to-down direction.

The details of the focused ion beam column 17 in one embodiment will be described below.

The optical axis of the electron beam column 15 and the optical axis of the focused ion beam column 17 intersect each other, for example, at a predetermined position P above the sample stand 13.

The relative positional arrangement of the electron beam column 15 and the focused ion beam column 17 may be changed as appropriate. For example, the electron beam column 15 may be arranged in the top-to-bottom direction, and the focused ion beam column 17 may be positioned in the tilt or orthogonal direction with respect to the top-to-bottom.

The charged particle beam device 10 can perform imaging of the irradiated region, various types of processing (such as drilling and trimming) based on sputtering, deposition film formation, etc., by scanning the surface of the irradiation target object with a focused ion beam. The charged particle beam device 10 can perform predetermined processing on the sample S to form sample pieces (for example, lamella samples and needle-shaped samples) for transmission electron microscopic observation and to form analytical sample pieces for electron beam analysis. The charged particle beam device 10 can perform processing on a sample piece transferred to the sample piece holder into a thin film with the desired thickness suitable for transmission electron microscopic observation. The charged particle beam device 10 enables observation of the surface of the irradiation target object by scanning the surface of the irradiation target object such as a sample S, a sample piece, and a needle with an ion beam or electron beam.

The secondary charged particle detector 21 detects secondary charged particles (secondary electrons and secondary ions) generated from the irradiation target object irradiated with an ion or electron beam. The secondary charged particle detector 21 is connected to the control device 25, and the detection signal output from the secondary charged particle detector 21 is transmitted to the control device 25.

The detector of the charged particle beam device 10 is not limited to the secondary charged particle detector 21, and other types of detectors can be used. Examples of the detector include energy dispersive X-ray spectrometer (EDS) detectors, backscattered-electron detectors, and electron back-scattering diffraction (EBSD) detectors. The EDS detector detects X-rays generated from the irradiation target object irradiated with an electron beam. The backscattered-electron detector detects backscattered electrons generated from the irradiation target object irradiated with an electron beam. The EBSD detector detects an electron beam backscatter diffraction pattern generated from the irradiation target object irradiated with an electron beam. Among the secondary charged particle detectors 21, the secondary charged particle detector 21 that detects secondary electrons, and the backscattered-electron detector may be housed in the casing of the electron beam column 15.

The gas supply unit 23 is fixed to the sample chamber 11. The gas supply unit 23 is equipped with a gas injection unit (nozzle) that is positioned facing the stage 31. The gas supply unit 23 supplies etching gas, deposition gas, and the like to the irradiation target object. The etching gas selectively promotes the etching of the irradiation target object by a focused ion beam, depending on the material of the irradiation target object. The deposition gas forms a deposition film made of metal or insulator deposits on the surface of the irradiation target object.

The gas supply unit 23 is controlled by control signals output from the control device 25 according to the operation modes of the charged particle beam device 10 and other factors.

The control device 25 controls the overall operation of the charged particle beam device 10 by, for example, signals input from the input device 27 or signals generated by a predetermined automatic operation control process.

The control device 25 is a software functional unit that functions in a manner that a processor such as a central processing unit (CPU) executes a predetermined program. The software functional unit is an electronic control unit (ECU) equipped with electronic circuits such as a processor such as a CPU, a read only memory (ROM) that stores programs, a random access memory (RAM) unit that temporarily stores data and a timer. At least part of the control device 25 may be an integrated circuit (IC) such as a large scale integrated (LSI) circuit.

The input device 27 is, for example, a mouse and keyboard that output signals in response to input operations made by the operator.

The display device 29 displays various information of the charged particle beam device 10, image data generated based on signals output from the secondary charged particle detector 21, and screens for allowing operations such as zooming in, zooming out, moving, and rotating the image data.

### Focused Ion Beam Column

FIG. 2 is a view illustrating the construction of the focused ion beam column 17 used in one embodiment.

The focused ion beam column 17 includes an ion source 41 and an ion optics 42. The ion source 41 and the ion optics 42 are controlled by control signals output from the control device 25 according to the focused ion beam irradiation position and irradiation conditions.

The ion source 41 generates ions. The ion source 41 may be, for example, a plasma ion source using inductive coupling or electron cyclotron resonance (ECR). In addition, the ion source 41 may be, for example, a liquid metal ion source using liquid gallium or the like, or a gas field emission ion source.

The ion optics 42 focuses and deflects the beam of ions (ion beam) extracted from the ion source 41. The ion optics 42 can switch the optical conditions to one of several modes, such as focusing mode and projection mode described below. The ion optics 42 includes an extraction electrode 51, a condenser lens 52, a blanker 53, a movable diaphragm 54, an alignment 55, a stigmeter 56, a scanning electrode 57, and objective lenses 58 that are arranged in this order from the ion source 41 side to the emission end 17a side (i.e., sample S side) of the focused ion beam column 17.

The extraction electrode 51 extracts ions from the ion source 41 by means of an electric field generated between the extraction electrode and the ion source 41. The voltage applied to the extraction electrode 51 is controlled according to, for example, the acceleration voltage for an ion beam, and the potential difference between the acceleration voltage applied to the ion source 41 and the voltage applied to the extraction electrode 51 is maintained at a constant level.

The condenser lens 52 includes, for example, a first condenser lens 52a and a second condenser lens 52b arranged along the optical axis. Each of the first and second condenser lenses 52a and 52b is, for example, an electrostatic lens equipped with three electrodes arranged along the optical axis.

The condenser lens 52 focuses the ion beam extracted from the ion source 41 by the extraction electrode 51. In the condenser lens 52, the applied voltage is adjusted according to the optical conditions of the focused ion beam column 17, thereby changing the lens strength related to the degree of convergence of the ion beam.

The blanker 53, alignment 55, and scanning electrode 57 constitute an electrostatic deflector 59 that deflects an ion beam. The stigmeter 56 constitutes an aberration corrector for shaping a beam.

The blanker 53 is equipped with, for example, a pair of electrodes (blanking electrodes) that are positioned to face each other so as to sandwich the optical axis from both sides in a direction that intersects the traveling direction of the ion beam. The blanker 53 toggles between blocking and unblocking of the ion beam. For example, the blanker 53 blocks the ion beam by deflecting the ion beam so that the ion beam strikes a blanking aperture (not shown) and releases the blocking by not deflecting the ion beam.

FIG. 3 is a view illustrating the construction of a movable diaphragm 54.

As illustrated in FIGS. 2 and 3, the movable diaphragm 54 includes a drive mechanism 54a and a diaphragm member 54b.

The drive mechanism 54a is controlled by control signals that are output from the control device 25 according to on the operation modes of the charged particle beam device 10. For example, the drive mechanism 54a includes an actuator that drives in at least one axial direction. The actuator is, for example, a piezoelectric actuator. The actuator drives in an arbitrary axial direction in the plane intersecting the optical axis of the focused ion beam column 17. Since the actuator drives in the X-axis direction that is orthogonal to the optical axis of the focused ion beam column 17, thereby moving the diaphragm member 54b backwards and forwards in each of the X-axis direction.

The external form of the diaphragm member 54b is a plate shape provided with a plurality of through-holes arranged along a predetermined direction. The predetermined direction is the driving direction of the drive mechanism 54a and is, for example, the X-axis direction. The multiple through-holes are switched to select any through-hole to allow at least a portion of the ion beam to pass through, depending on operation of the diaphragm member 54b driven by the drive mechanism 54a. The multiple through-holes include, for example, circular holes 61 for observation, first rectangular holes 62 for processing, and second rectangular holes for observation and processing.

The diameter r of the circular hole 61 is relatively small, for example, less than 5 μm. The center of the circular hole 61 is positioned at a first reference position Q1 which is aligned with the center (beam center) of the optical axis of the focused ion beam column 17.

The external form of the first rectangular hole 62 is, for example, a square having a size on one side is larger than the diameter r of the circular hole 61 and is 1 mm or less. The first rectangular hole 62 is displaced by a predetermined distance La in a predetermined direction (for example, in the X-axis direction) from a second reference position Q2, which is aligned with the center of the optical axis of the focused ion beam column 17, so that a predetermined range including the center of the optical axis of the focused ion beam column 17 is shielded by the diaphragm member 54b. Of the four sides (edges) of the first rectangular hole 62, one side 62a closest to the second reference position Q2 is parallel to a direction (for example, Y-axis direction) orthogonal to the predetermined direction, and the distance between the side 62a and the second reference position Q2 is the predetermined distance La. The predetermined distance La is, for example, greater than zero and is 500 μm or less. The predetermined distance La is more preferably greater than zero and is 50 μm or less. In addition, the predetermined distance La may be, for example, about 1.2 to 1.5 times half the length of the first rectangular hole 62 in the predetermined direction (for example, in the X-axis direction).

The external form of the second rectangular hole 63 is, for example, a rectangular whose shorter-side size is almost equal to the diameter of the circular hole 61 for observation and whose longer-side size is almost equal to the size of one side of the first rectangular hole 62. The second rectangular hole 63 is displaced by a predetermined distance La in a predetermined direction (for example, in the X-axis direction) from a third reference position Q3, which is aligned with the center of the optical axis of the focused ion beam column 17, so that a predetermined range including the center of the optical axis of the focused ion beam column 17 is shielded by the diaphragm member 54b. Of the four sides (edges) of the second rectangular hole 63, one side 63a closest to the third reference position Q3 is parallel to a direction (for example, Y-axis direction) orthogonal to the predetermined direction, and the distance between the side 63a and the third reference position Q3 is the predetermined distance La.

As illustrated in FIG. 2, each of the alignment 55, stigmeter 56, and scanning electrode 57 is composed of, for example, a plurality of electrodes or the like arranged in a cylindrical shape around the optical axis of the ion beam.

The alignment 55 adjusts the trajectory of the ion beam so that the ion beam can pass through the central axis of the objective lens 28.

The stigmeter 56 corrects astigmatism of the ion beam.

The scanning electrode 57 causes the ion beam having passed through the objective lens 58 to scan over the sample. The scanning electrode 57, for example, performs raster scanning for a rectangular area on the surface of the sample S by applying a deflection voltage for two-dimensional scanning.

The objective lens 58 is, for example, an electrostatic lens with three electrodes arranged along the optical axis. The objective lens 58 focuses the ion beam on the sample S. In the objective lens 58, the applied voltage is adjusted according to the optical conditions of the focused ion beam column 17, thereby changing the lens strength related to the degree of convergence of the ion beam and the size of the beam shape.

The ion optics 42 can switch the optical conditions among several modes, such as focusing mode and projection mode.

In the focusing mode, the ion beam trajectories do not intersect with each other but are nearly parallel with each other between the condenser lens 52 and the objective lens 58, and the angular spread of the ion beam is adjusted by the movable diaphragm 54. In the focusing mode, the sample S is scanned with an ion beam that is focused on the sample S by the objective lens 58 and deflected by the electrostatic deflector 59.

The projection mode is based on the Köhler illumination method, which is the so-called uniform illumination method, and projects the ion beam, which is formed by the movable diaphragm 54 corresponding to a field stop, onto the sample S without scanning. In the projection mode, the objective lens 58 makes the movable diaphragm 54 the light source and focuses the ion beam with a beam shape cut by the movable diaphragm 54 onto the sample S. In the projection mode, scanning may be performed to expand the irradiation range or other purposes.

The ion optics 42 uses, as the projection mode, for example, a second projection mode in which the voltage applied to the condenser lens 52 is relatively low compared to a first projection mode (standard projection mode).

FIG. 4 is a view illustrating an example of an ion beam trajectory according to an application voltage applied to the condenser lens 52 in the projection mode of the focused ion beam column 17. FIG. 5 is a view illustrating an example of a prove current intensity distribution on the surface of the sample S, corresponding to the beam trajectory shown in FIG. 4.

A first trajectory B1 shown in FIG. 4 is the trajectory of the ion beam for the case (first projection mode) in which the ion beam is focused on the main surface (or center) of the objective lens 58 by the application of a predetermined voltage V1 to the condenser lens 52. A second trajectory B2 shown in FIG. 4 is the trajectory of the ion beam for the case (second projection mode) in which the intensity of the ion beam focused by the condenser lens 52 is relatively weak compared to the first projection mode. The voltage V2 applied to the condenser lens 52 in the second projection mode is, for example, 0.8 or more times and less than 1.0 times a predetermined voltage V1 used in the first projection mode (i.e., (0.8×V1≤V2<V1). When the lens strength related to the degree of focusing of the ion beam focused by the condenser lens 52 in the first projection mode is set as a reference lens strength, and the lens strength of the condenser lens 52 in the second projection mode is 0.8 or more times and less than 1.0 times the reference lens strength.

As illustrated in FIG. 5, the intensity distribution D1 of the probe current I corresponding to the first trajectory B1 in the first projection mode is almost uniform in a given irradiation range including the irradiation center O on the sample S. The intensity distribution D2 of the probe current I corresponding to the second trajectory B2 in the second projection mode tends to increase from the periphery to the irradiation center O in a smaller irradiation range than a predetermined range in the first projection mode. The intensity of the probe current I at the irradiation center O in the intensity distribution D2 of the second projection mode is larger than that in the intensity distribution D1 of the first projection mode, and the beam intensity near the center O is stronger.

The ion optics 42, for example, switches and selects among the multiple through-holes of the movable diaphragm 54 while the second projection mode of the projection mode as the optical condition is maintained when processing and observation of the sample S are repeatedly performed.

FIG. 6 is a view illustrating an example of a position corresponding to a beam center C in the diaphragm member 54b of the movable diaphragm 54 of the focused ion beam column 17. FIG. 7 is a view illustrating an example of a position corresponding to a beam center C in a first rectangular hole 62 for processing, in the movable diaphragm 54. FIG. 8 is a view illustrating an example of the contour of a processing range on the surface of the sample S according to the position of the first rectangular hole 62 shown in FIG. 7.

When for example, positioning for observation and processing of the sample S is performed by using the fine circular hole 61 for observation of the movable diaphragm 54 shown in FIG. 3, in the second projection mode, the ion optics 42 aligns the center of the circular hole 61 with the beam center C by aligning the first reference position Q1 of the diaphragm member 54b with the beam center C.

For example, as illustrated in FIG. 6, when the sample S is to be processed through the first rectangular hole 62 for processing of the movable diaphragm 54, in the second projection mode, the ion optics 42 aligns the second reference position Q2 of the diaphragm member 54b with the beam center C. Therefore, the first rectangular hole 62 is displaced from the beam center C in the X-axis direction by a predetermined distance La, and a predetermined area including the beam center C is shielded by the diaphragm member 54b.

When observation or processing of the sample S is to be performed through the second rectangular hole 63 for observation and processing of the movable diaphragm 54, as with the case shown in FIG. 6, in the second projection mode, the ion optics 42 aligns the third reference position Q3 of the diaphragm member 54b with the beam center C. Therefore, the second rectangular hole 63 is displaced from the beam center C in the X-axis direction by a predetermined distance La, and a predetermined area including the beam center C is shielded by the diaphragm member 54b.

An embodiment shown in FIGS. 7 and 8 is identical to the state shown in FIG. 6. That is, the first rectangular hole 62 for processing of the movable diaphragm 54 is displaced from the beam center C in the X-axis direction by a predetermined distance La, and a predetermined range including the beam center C is shielded by the diaphragm member 54b. A first comparative example illustrated in FIGS. 7 and 8 is a state in which the center of the first rectangular hole 62 for processing of the movable diaphragm 54 is aligned with the beam center C. A second comparative example illustrated in FIGS. 7 and 8 is a state in which one side 62a (the side 62a closest to the second reference position Q2 among the four sides of the first rectangular hole 62) of the first rectangular hole 62 for processing of the movable diaphragm 54 is aligned with the beam center C in the X-axis direction.

As illustrated in FIG. 8, the embodiment provides a contour of a processing area with a straight edge E0 around the irradiation center O compared to the first and second comparative examples. In the first comparative example, it is not possible to obtain a contour of a processing area with an edge near the irradiation center O. In the second comparative example, a contour of a processing area with a curved edge E2 near the irradiation center O is obtained, and the edge E2 near the irradiation center O is not straight.

As illustrated in FIG. 5, in the second projection mode, the beam intensity changes in a manner to increase from the periphery of the irradiation region toward the irradiation center O. As illustrated in FIG. 8, according to the embodiment in which the contour of a processing region with a straight edge E0 near the irradiation center O is obtained, the straight edge E0 can be efficiently implemented with a relatively stronger beam intensity. In the embodiment, the beam intensity of the ion beam shaped by the movable diaphragm 54 changes in a manner to decrease from the irradiation center O toward the periphery of the irradiation region. Therefore, a groove shape with a sloping bottom that gradually becomes shallower from the deepest edge E0 toward the periphery of the irradiation region is obtained by a single time of beam irradiation without requiring scanning.

### Observation and Processing Process

FIG. 9 is a view illustrating an example of observation and processing of a sample S by a charged particle beam device.

Steps S01 and S02 shown in FIG. 9 are an example of repeating the process of preparing and observing a cross-section of a sample S, for example, for a three-dimensional structural analysis.

First, in step S01, the optical condition of the ion optics 42 of the focused ion beam column 17 is set to the second projection mode of the projection mode, so that the processing position is set by aligning the center of the circular hole 61 for observation of the movable diaphragm 54 with the beam center C. Then, with the optical condition of the ion optics 42 maintained in the second projection mode, the second reference position Q2 for the first rectangular hole 62 for processing of the movable diaphragm 54 is aligned with the beam center C, and the sample S is etched (rough processing) by the focused ion beam formed by the first rectangular hole 62. This creates a groove shape with a slope-like bottom surface B that gradually becomes shallower from the straight edge E0 to the periphery of the irradiation region, and a planar cross section CS is formed by the edge E0.

Next, in step S02, with the optical condition of the ion optics 42 maintained in the second projection mode, the third reference position Q3 for the second rectangular hole 63 for processing and observation of the movable diaphragm 54 is aligned with the beam center C, and the sample S is etched (finishing processing) by the focused ion beam formed by the second rectangular hole 63. This step is to finish the planar cross section CS with a straight edge E0. Prior to the finishing process using the second rectangular hole 63, the processing position may be confirmed by the circular hole 61 for observation.

Next, the cross section CS is observed by irradiating the cross-section CS with an electron beam by the electron beam column 15.

Next, for example, the processing position is transmitted based on a scanning signal, and the sample S is newly etched and processed by the focused ion beam formed by the second rectangular hole 63 for processing and observation of the movable diaphragm 54 to produce a new cross section CS.

Next, the new cross section CS is observed using the electron beam of the electron beam column 15.

Hereafter, the production of the cross section CS of the sample S by using the focused ion beam shaped by the second rectangular hole 63 of the movable diaphragm 54 and the observation of the cross section CS by using the electron beam of the electron beam column 15 are performed repeatedly.

Steps S01 and S03 shown in FIG. 9 are an example of preparing a sample piece Sp, such as a lamella sample for transmission observation by transmission electron microscopy, from a sample S.

After the execution of step S01, in step S03, first, a processing position is set by aligning the center of the circular hole 61 for observation of the movable diaphragm 54 with the beam center C. The new processing position is, for example, a position opposite to the irradiation range of step S01 in the X-axis direction with respect to the desired sample piece Sp so that a sample piece Sp with a predetermined thickness in the X-axis direction can be formed. Next, with the optical condition of the ion optics 42 maintained in the second projection mode, for example, the first rectangular hole 62 is placed at a position symmetrical to the position of the first rectangular hole 62 of step S01 with respect to the beam center C in the X axis direction. The sample S is etched (rough processing) by the focused ion beam shaped by the first rectangular hole 62 on the opposite side of the irradiation range of step S01 in the X-axis direction with respect to the desired sample piece Sp. This produces a groove shape with a slope-like bottom surface B that gradually becomes shallower from the straight edge E0 to the periphery of the irradiation region on the side opposite to the irradiation range of step S01 in the X-axis direction with the desired sample piece Sp, and a planar cross section CS is formed by the edge E0.

In addition, when setting the processing position in step S01 and step S03, the second rectangular hole 63 for processing and observation may be used instead of the circular hole 61 for observation, or a mark indicating the processing position may be processed on both sides of the processing region by using the second rectangular hole 63.

For example, when the second rectangular hole 63 is used for observation, since the short side (width in the X-axis direction) of the second rectangular hole 63 is as small as the diameter of the circular hole 61 for observation, the beam irradiation range in the X-axis direction is reduced, observation and processing position determination can be performed with good accuracy in the X-axis direction.

In addition, when the second rectangular hole 63 is used for processing, the long side (width in the Y-axis direction) of the second rectangular hole 63 is as large as one side of the first rectangular hole 62 for processing, the beam irradiation range in the Y-axis direction is increased, thereby enabling efficient processing in the Y-axis direction in a short time.

In addition, after the execution of the etching process (rough processing) of step 01 and step S03, the processing position may be confirmed by using the circular hole 61 for observation and the etching process (finishing process) of the sample S may be performed by using the second rectangular hole 63.

As described above, since the charged particle beam device 10 of the embodiment is equipped with the diaphragm member 54b having a circular hole 61 for observation, a first rectangular hole 62 for processing, and a second rectangular hole 63 for observation and processing, which can be switched while the optical conditions of the ion optics 42 are maintained, positional accuracy of the position for processing with the focused ion beam can be improved. For example, the reproducibility of the beam irradiation position can be improved by maintaining the optical conditions, compared to the case where multiple optical conditions, such as lens voltage and other optical settings, are switched for each of observation and processing, such as focusing mode for observation and projection mode for processing of which optical conditions are significantly different.

Since the optical condition of the ion optics 42 is maintained as the projection mode, a large area can be efficiently processed by an ion beam irradiation without requiring scanning compared to the focusing mode. Even though the optical condition is the projection mode, positioning for observation and processing can be performed with good accuracy by selecting a fine circular hole 61 for observation.

Since the optical condition is maintained as the second projection mode of the projection mode, the beam intensity at the irradiation center O is increased compared to the first projection mode with uniform illumination, the desired beam intensity can be secured by using the circular hole 61 arranged at the beam center C during observation. During processing, since each of the rectangular holes 62 and 63 is positioned off the beam center C, and each of the linear sides 62a and 63a which form a straight edge E0, is positioned near the beam center C, cross section processing can be efficiently performed.

### Modification

Hereinafter, a modification to the embodiment will be described. The same parts as those in the embodiment described above will be given the same reference symbols, and the description thereof will be omitted or simplified.

In the embodiment described above, the plurality of through-holes in the diaphragm member 54b includes a first rectangular hole 62 for processing and a second rectangular hole 63 for observation and processing, but it is not limited thereto. The plurality of through-holes may include other shapes of holes other than rectangular holes. For example, instead of the first rectangular hole 62, an appropriately shaped through-hole with at least one straight side 62a closest to the second reference position Q2 may be formed. For example, instead of the second rectangular hole 63, an appropriately shaped through-hole with at least one straight side 63a closest to the third reference position Q3 may be formed.

In the embodiment described above, the ion optics 42 of the focused ion beam column 17 is equipped with one movable diaphragm 54, but it is not limited thereto. the ion optics 42 may be equipped with a plurality of movable diaphragms each of which does not interfere with the passage of the ion beams passing through the other movable diaphragms.

FIG. 10 is a view illustrating the construction of the focused ion beam column 17A used in a modification to one embodiment. FIG. 11 is a view illustrating the construction of a first movable diaphragm 71 of a focused ion beam column 17A in the modification. FIG. 12 is a view illustrating the construction of a second movable diaphragm 72 of a focused ion beam column 17A in the modification.

As illustrated in FIG. 10, the ion optics 42A of the focused ion beam column 17A in the modification includes, for example, a first movable diaphragm 71 and a second diaphragm 72 arranged along the optical axis, as a plurality of movable diaphragms. The first movable diaphragm 71 includes a first drive mechanism 71a and a first diaphragm member 71b. The second movable diaphragm 72 includes a second drive mechanism 72a and a second diaphragm member 72b. Each of the first drive mechanism 71a and the second drive mechanism 72a includes, for example, an actuator that drives in at least one axial direction (for example, X-axis direction). The external form of each of the first diaphragm member 71b and the second diaphragm member 72b is a plate shape with a plurality of through-holes arranged along a predetermined direction. The predetermined direction is the driving direction of each of the drive mechanisms 71a and 72a. For example, the direction is the X-axis direction. The multiple through-holes 55c are switched to allow the passage of a portion of the ion beam according to an operation of one of the diaphragms 71b and 72b by each of the drive mechanisms 71a and 72a.

As illustrated in FIG. 11, the multiple through-holes of the first diaphragm member 71b include, for example, a first circular-hole 81 for observation, a second circular-hole 82 for observation, and a third circular hole 83 for image beam passage.

The first circular hole 81 corresponds to the circular hole 61 of the embodiment. The diameter r1 of the first circular hole 81 is relatively small and is, for example, 5 μm or less. The center of the first circular hole 81 is positioned at a first reference position Q11 which is aligned with the center (beam center) of the optical axis of the focused ion beam column 17.

The diameter r2 of the second circular hole 82 is, for example, larger than the diameter r1 of the first circular hole 81. The center of the second circular hole 82 is positioned at a second reference position Q12 which is aligned with the center (beam center) of the optical axis of the focused ion beam column 17.

The diameter r3 of the third circular hole 83 is a size that does not block the ion beam passing through each of the third and fourth rectangular holes 92 and 93 of the second diaphragm member 72b described below. The center of the third circular hole 83 is at the same position as the third reference position Q13 aligned with the center (beam center) of the optical axis of the focused ion beam column 17.

As illustrated in FIG. 12, the multiple through-holes of the second diaphragm member 72b include, for example, a fourth circular hole 91 for ion beam passage, a third rectangular hole 92 for processing, and a fourth rectangular hole 93 for observation and processing.

The radius r4 of the fourth circular hole 91 is a size that does not block the ion beam passing through each of the first and second circular holes 81 and 82 of the first diaphragm member 71b described below. The center of the fourth circular hole 91 is at the same position as the fourth reference position Q21 aligned with the center (beam center) of the optical axis of the focused ion beam column 17.

The third rectangular hole 92 and the fourth rectangular hole 93 correspond to the first rectangular hole 62 and the second rectangular hole 63 of the embodiment.

The external form of the third rectangular hole 92 is identical to the external form of the first rectangular hole 62 in the embodiment. The third rectangular hole 92 is displaced by a predetermined distance La in a predetermined direction (for example, in the X-axis direction) from a fifth reference position Q22, which is aligned with the center of the optical axis of the focused ion beam column 17, so that a predetermined range including the center of the optical axis of the focused ion beam column 17 is shielded by the diaphragm member 72b. Of the four sides (edges) of the third rectangular hole 92, one side 92a closest to the fifth reference position Q22 is parallel to a direction (for example, Y-axis direction) orthogonal to the predetermined direction, and the distance between the side 92a and the fifth reference position Q22 is the predetermined distance La.

The external form of the fourth rectangular hole 93 is identical to the external form of the second rectangular hole 63 in the embodiment. The fourth rectangular hole 93 is displaced by a predetermined distance La in a predetermined direction (for example, in the X-axis direction) from a sixth reference position Q23, which is aligned with the center of the optical axis of the focused ion beam column 17, so that a predetermined range including the center of the optical axis of the focused ion beam column 17 is shielded by the diaphragm member 72b. Of the four sides (edges) of the fourth rectangular hole 93, one side 93a (longer side) closest to the sixth reference position Q23 is parallel to a direction (for example, Y-axis direction) orthogonal to the predetermined direction, and the distance between the side 93a and the sixth reference position Q23 is the predetermined distance La.

The ion optics 42A positions the first circular hole 81 or the second circular hole 82 of the first diaphragm member 71b at the center of the optical axis, and positions the fourth circular hole 91 of the second diaphragm member 72b at the center of the optical axis during observation. Alternatively, the ion optics 42A may, under the condition of the second projection mode, position the first circular hole 81 or the second circular hole 82 of the first diaphragm member 71b at the center of the optical axis, and the third rectangular hole 92 or the fourth rectangular hole 93 of the second diaphragm member 72b to be displaced by a predetermined distance la in a predetermined direction (for example, the X-axis direction) from the center of the optical axis. In ion optics 42A, during processing, the third circular hole 83 of the first diaphragm member 71b is arranged at the center of the optical axis, and the third rectangular hole 92 or fourth rectangular hole 93 of the second diaphragm member 72b is displaced by a predetermined distance la in a predetermined direction (for example, in the X-axis direction) from the center of the optical axis. When the third rectangular hole 92 or fourth rectangular hole 93 of the second diaphragm member 72b is displaced from the center of the optical axis by a predetermined distance La in a predetermined direction (for example, the X-axis direction) during observation as described above, the processing beam can be switched by moving the third circular hole 83 of the first diaphragm member 71b without moving the second diaphragm member 72 during processing. Therefore, the processing position can be determined with good reproducibility.

The ion optics 42A may move the second diaphragm member 72b to a position at which there is no interference with the ion beam during observation and the first diaphragm member 71b to a position at which there is not interference with the ion beam during processing.

In the embodiment described above, the charged particle beam device 10 is equipped with the electron beam column 15 and the focused ion beam column 17, but the present invention is not limited thereto. For example, the charged particle beam device 10 may not be equipped with the electron beam column 15 but may be equipped with only the focused ion beam column 17.

The embodiments of the invention are presented for illustrative purposes and are not intended to limit the scope of the invention. These embodiments can be implemented in various other forms, and various omissions, substitutions, and changes can be made without departing from the gist of the invention.

These embodiments and modifications thereto fall within the scope and idea of the inventions and also fall within the scopes of the inventions defined in the claims and their equivalents.

### EXPLANATION OF REFERENCE NUMERALS

10 . . . Charged particle beam device, 11 . . . Sample chamber, 12 . . . Sample holder, 13 . . . Sample stand, 15 . . . Electron beam column, 17, 17A . . . Focused ion beam column, 21. . . . Secondary charged particle detector, 23 . . . Gas supply unit, 25 . . . Control device, 27 . . . Input device, 29 . . . Display device, 41 . . . Ion source (charged particle source), 42, 42A . . . Ion optics, 52 . . . Condenser lens, 54 . . . Movable diaphragm, 54b . . . Diaphragm member, 58 . . . Objective lens, 61 . . . Circular hole (first through-hole), 62 . . . First rectangular hole (second through-hole), 62a . . . Edge, 63 . . . Second rectangular hole (third through-hole), 63a . . . Edge, 71b . . . First diaphragm member, 71 . . . First movable diaphragm, 72 . . . Second movable diaphragm, 72b . . . Second diaphragm member, 81 . . . First circular hole (first through-hole), 82 82 . . . Second circular hole, 83 . . . Third circular hole, 91 . . . Fourth circular hole, 92 . . . Third rectangular hole (second through-hole), 92a . . . Edge, 93 . . . Fourth rectangular hole (third through-hole), 93a . . . Edge, C . . . Beam center, S . . . Sample.

1. A charged particle beam device comprising:
a charged particle source generating charged particles;
a diaphragm member where a plurality of through-holes is formed that are switched to pass a portion of a beam of charged particles generated from the charged particle source; and
an optics irradiating a sample with the beam of charged particles passing through each of the plurality of through-holes,
wherein the plurality of through-holes is switched to any one in a state in which the optics maintains an optical condition of a predetermined projection mode and the plurality of through-holes comprises at least a first through-hole positioned at a center of the beam of the charged particles and a second through-hole placed off-center of the beam of the charged particles.

2. The charged particle beam device according to claim 1, wherein the plurality of through-holes comprises at least the first through-hole, the second through-hole, and a third through-hole that is placed off-center of the beam of charged particles, a size of the third through-hole in a direction of displacement from the center of the beam of charged particles being equal to a size of the first through-hole and a size of the third through-hole in a direction orthogonal to the direction of displacement from the center of the beam of charged particles being equal to a size of the second through-hole.

3. A charged particle beam device comprising:
a charged particle source generating charged particles;
a plurality of diaphragm members where at least one through-hole is formed that passes a portion of a beam of charged particles generated from the charged particle source; and
an optics irradiating a sample with the beam of charged particles passing through the through-holes of each of the plurality of diaphragm members,
wherein the plurality of diaphragm members does not interfere with one another with respect to passage of the beam of charged particles and comprises, in a state in which the optics maintains an optical condition of a predetermined projection mode, at least a first diaphragm member having a first through-hole placed at a center of the beams of charged particles and a second diaphragm member having a second through-hole placed off-center of the beam of charged particles.

4. The charged particle beam device according to claim 3, wherein the at least one through-hole formed on the second diaphragm member comprises:
the second through-hole; and
a third-through-hole that is placed off-center of the beam of charged particles in a state in which the optics maintains a predetermined optical condition, a size of the third through-hole in a direction of displacement from the center of the beam of charged particles being equal to a size of the first through-hole and a size of the third through-hole in a direction orthogonal to the direction of displacement from the center of the beam of charged particles being equal to a size of the second through-hole.

5. The charged particle beam device according to claim 2, wherein an edge of each of the second and third through-holes closest to the center of the beam of charged particles is of a linear shape in parallel to the direction orthogonal to the direction of displacement from the center of the beam of charged particles.

6. A charged particle beam device comprising:
a charged particle source generating charged particles; and
an optics comprising a diaphragm member where a plurality of through-holes is formed that are switched to pass a portion of a beam of the charged particles generated from the charged particle source, the optics irradiating a sample with the beam of charged particles passing through each of the plurality of through-holes,
wherein the plurality of through-holes is switched to any one in a state in which the optics maintains a predetermined optical condition and the plurality of through-holes comprises at least a first through-hole positioned at a center of the beam of the charged particles and a second through-hole placed off-center of the beam of charged particles and
wherein the optics comprises:
a condenser lens placed between the charged particle source and the diaphragm member to focus the beam of charged particles; and
an objective lens placed between the diaphragm member and the sample to focus the beam of charged particles on the sample and
wherein the predetermined optical condition, with lens power in case of focusing the beam of charged particles on the sample in a beam shape cut by the diaphragm member with the diaphragm member as a light source by the objective lens, based on the Koehler illumination method, and focusing the beam of charged particles on a predetermined location of the objective lens by the condenser lens as standard lens power, is that lens power of the condenser lens is greater than or equal to 0.8 times and less than 1.0 times the standard lens power.
